(19) United States
(12) Patent Application Publication
(10) Pub. No.: US 2024/0072168 A1
(43) Pub. Date: Feb. 29, 2024

(54) Method for Forming SiGe Channel

(71) Applicant: Shanghai Huali Integrated Circuit Corporation, Shanghai (CN)

(72) Inventor: Xinhua Cheng, Shanghai (CN)

(73) Assignee: Shanghai Huali Integrated Circuit Corporation, Shanghai (CN)

(21) Appl. No.: 18/135,315

(22) Filed: Apr. 17, 2023

(30) Foreign Application Priority Data
Aug. 25, 2022 (CN) 202211022397.5

(51) Int. Cl. H01L 29/78; H01L 21/02; H01L 21/225; H01L 21/84; H01L 27/12; H01L 29/161; H01L 29/66

(52) U.S. Cl. CPC H01L 29/7838; H01L 21/02236; H01L 21/02532; H01L 21/2254; H01L 21/84; H01L 27/1203; H01L 29/161; H01L 29/66477

(57) ABSTRACT

The present application provides a method for forming a SiGe channel, FDSOI structure comprising a silicon substrate, a first silicon oxide layer and a silicon layer, wherein the silicon layer is covered with a hard mask layer, a groove region that penetrates through upper and lower surfaces of the hard mask layer is formed on the hard mask layer, and the groove region exposes an upper surface of the silicon layer; forming a SiGe film in the groove region; forming a second silicon oxide layer on an upper surface of the SiGe film; removing the hard mask layer; and performing a thermal treatment on the stack structure in an atmosphere of ammonia and oxygen to form a SiO2-SiGe channel. According to the present application, the SiGe channel is formed to reduce a relaxation risk of SiGe during a subsequent thermal treatment process.

### CROSS-REFERENCE TO RELATED APPLICATIONS

This application claims priority to Chinese Patent Application No. CN 202211022397.5, filed on Aug. 25, 2022, the disclosure of which is incorporated herein by reference in its entirety.

### TECHNICAL FIELD

The present application relates to the technical field of semiconductors, in particular to a method for forming a SiGe channel.

### BACKGROUND

In a fully depleted silicon on insulator (FDSOI) structure, conventionally, selective epitaxy is performed to grow SiGe on an exposed silicon surface of FDSOI, so as to form a SiGe/Si construction. Then a layer of silicon oxide is grown over the SiGe, with the assistance of a thermal annealing process. During the thermal annealing process, SiO2 on the surface reacts with Si in the SiGe, and Ge atoms diffuse downward under a thermal action, forming a SiGe channel with Si on the surface of FDSOI. Then SiOx on the surface is removed by means of an etching process, and denser SiOx which is to be used as a gate oxide of the device is formed by means of a thermal process. This method includes two thermal processes with a relatively large thermal budget, significantly limiting the concentration of Ge in the epitaxial growth of SiGe, and limiting the improvement of device performance within a certain range. Moreover, as Ge was introduced into the upper Si of FDSOI earlier to form a SiGe channel, a relaxation risk of SiGe due to a thermal treatment during a subsequent process is increased.

### BRIEF SUMMARY

In view of the above defect in the prior art, the objective of the present application is to provide a method for forming a SiGe channel, so as to solve the problem of a relaxation risk of SiGe due to a thermal treatment during an FDSOI process in the prior art.

In order to achieve the above objective and other related objectives, the present application provides a method for forming a SiGe channel, at least including the following steps:
step 1, providing an FDSOI structure, the FDSOI structure including a silicon substrate, a first silicon oxide layer located on the silicon substrate, and a silicon layer located on the first silicon oxide layer, wherein the silicon layer is covered with a hard mask layer, a groove region that penetrates through upper and lower surfaces of the hard mask layer is formed on the hard mask layer, and the groove region exposes an upper surface of the silicon layer;
step 2, filling the groove region with SiGe to form a SiGe film;
step 3, forming a second silicon oxide layer on an upper surface of the SiGe film, wherein the second silicon oxide layer, the SiGe film, and the silicon layer under the SiGe film form a stack structure;
step 4, removing the hard mask layer; and
step 5, performing a thermal treatment on the stack structure in an atmosphere of ammonia and oxygen to form a SiO2-SiGe channel.

In an example, in step 2, the groove region is filled with the SiGe by means of epitaxial growth.

In an example, in step 3, the second silicon oxide layer is formed on the upper surface of the SiGe film by oxidizing the SiGe film.

In an example, a method of forming the SiO2-SiGe channel in step 5 is as follows: Ge atoms in the SiGe film diffuse into the silicon layer under a thermal action, and form a SiGe channel with Si in the silicon layer; Si in the SiGe film is oxidized to form a third silicon oxide layer; and the second silicon oxide layer, the third silicon oxide layer, and the SiGe channel jointly form the SiO2-SiGe channel.

In an example, a flow of the ammonia in step 5 is 5-20 L.

In an example, a temperature of the thermal treatment in step 5 is 850-1100° C.

In an example, a time for introducing the ammonia in step 5 is 1-5 min.

In an example, a flow of the oxygen in step 5 is 30-250 ml.

In an example, a time for introducing the oxygen in step 5 is 30 s to 3 min.

In an example, a pressure of the atmosphere of ammonia and oxygen in step 5 is 3-20 torr.

As stated above, the method for forming a SiGe channel of the preset application has the following beneficial effects: according to the present application, the SiGe channel is formed to reduce a relaxation risk of SiGe during a subsequent thermal treatment process. A small amount of oxygen is introduced at the same time when the ammonia propels Ge atoms, so as to effectively alleviate a damage on the surface of a gate oxide caused by the removal of a hard mask, effectively reduce defects of a Si/SiGe interface, and reduce a flat-band voltage Vfb of SiO2, thus obtaining the gate oxide with a better quality.

### BRIEF DESCRIPTION OF THE DRAWINGS

FIG. 1 is a schematic diagram of a longitudinal section of an FDSOI structure according to the present application.

FIG. 2 is a schematic sectional diagram of a structure where a SiGe film is formed in a groove region according to the present application.

FIG. 3 is a schematic sectional diagram of a structure where a second silicon oxide layer is formed on the SiGe film according to the present application.

FIG. 4 is a schematic sectional diagram of a structure where a hard mask layer is removed according to the present application.

FIG. 5 is a schematic sectional diagram of a structure where a SiO2-SiGe channel is formed according to the present application.

FIG. 6 is a flowchart of a method for forming a SiGe channel according to the present application.

### DETAILED DESCRIPTION OF THE DISCLOSURE

The embodiments of the present application are described below using specific examples, and those skilled in the art can easily understand other advantages and effects of the present application from the contents disclosed in the Description. The present application can also be implemented or applied using other different specific embodiments, and various details in the Description can also be modified or changed based on different viewpoints and applications without departing from the spirit of the present application.

Please refer to FIGS. 1-6. It should be noted that the drawings provided in this embodiment are only used to illustrate the basic concept of the present application in a schematic way, so the drawings only show the components related to the present application rather than being drawn according to the number, shape and size of the components in actual implementation. The type, number and proportion of various components can be changed randomly during actual implementation, and the layout of components may be more complicated.

The present application provides a method for forming a SiGe channel. Referring to FIG. 6, FIG. 6 is a flowchart of the method for forming a SiGe channel according to the present application. The method at least includes the following steps.
Step 1. An FDSOI structure is provided, the FDSOI structure including a silicon substrate, a first silicon oxide layer located on the silicon substrate, and a silicon layer located on the first silicon oxide layer, wherein the silicon layer is covered with a hard mask layer, a groove region that penetrates through upper and lower surfaces of the hard mask layer is formed on the hard mask layer, and the groove region exposes an upper surface of the silicon layer.

Referring to FIG. 1, FIG. 1 is a schematic diagram of a longitudinal section of the FDSOI structure according to the present application. In step 1, the FDSOI structure is provided, the FDSOI structure including the silicon substrate 01, the first silicon oxide layer 02 located on the silicon substrate 01, and the silicon layer 03 located on the first silicon oxide layer 02, wherein the silicon layer 03 is covered with the hard mask layer 04, the groove region 05 that penetrates through upper and lower surfaces of the hard mask layer 04 is formed on the hard mask layer, and the groove region 05 exposes an upper surface of the silicon layer 03.
Step 2. The groove region is filled with SiGe to form a SiGe film.

According to this embodiment of the present application, in step 2, the groove region is filled with the SiGe by means of epitaxial growth.

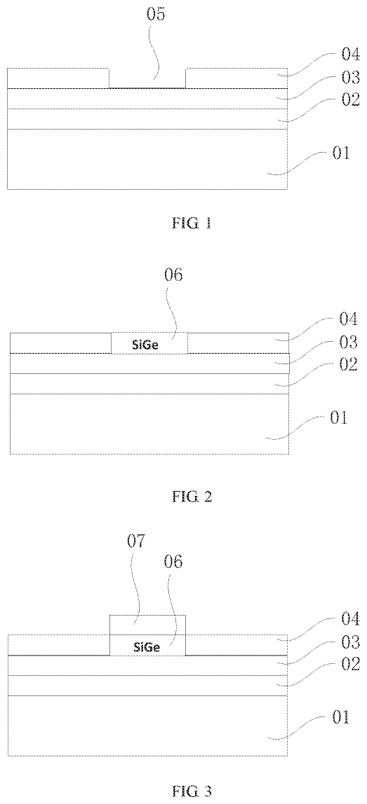

Referring to FIG. 2, FIG. 2 is a schematic sectional diagram of a structure where the SiGe film is formed in the groove region according to the present application. In step 2, the groove region 05 is filled with SiGe to form the SiGe film 06. According to this embodiment, the groove region 05 is filled with the SiGe by means of epitaxial growth.

Step 3. A second silicon oxide layer is formed on an upper surface of the SiGe film, wherein the second silicon oxide layer, the SiGe film, and the silicon layer under the SiGe film form a stack structure.

According to this embodiment of the present application, in step 3, the second silicon oxide layer is formed on the upper surface of the SiGe film by oxidizing the SiGe film.

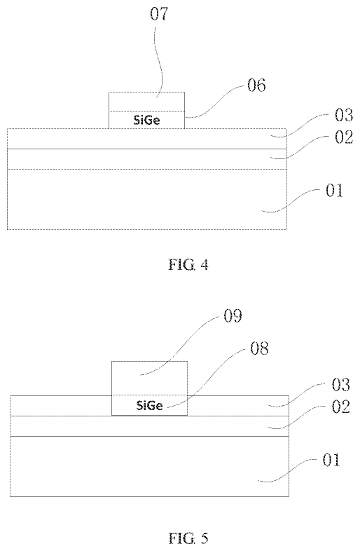

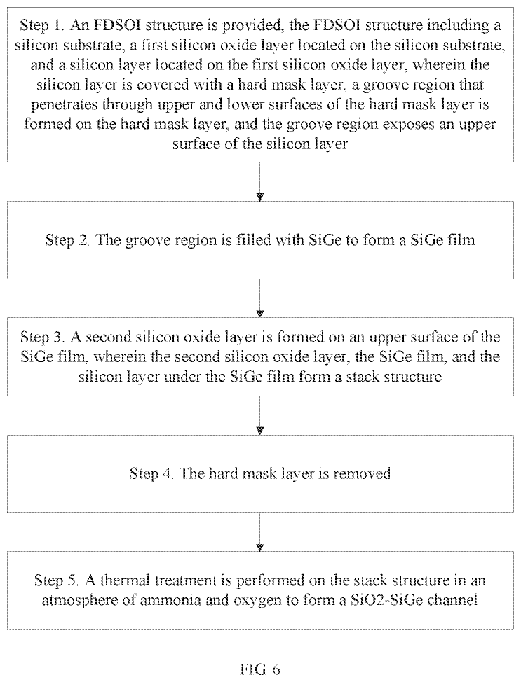

Referring to FIG. 3, FIG. 3 is a schematic sectional diagram of a structure where the second silicon oxide layer is formed on the SiGe film according to the present application. In step 3, the second silicon oxide layer 07 is formed on the upper surface of the SiGe film 06, wherein the second silicon oxide layer 07, the SiGe film 06, and the silicon layer 03 under the SiGe film form the stack structure. According to this embodiment, in step 3, the second silicon oxide layer 07 is formed on the upper surface of the SiGe film 06 by oxidizing the SiGe film.
Step 4. The hard mask layer is removed. Referring to FIG. 4, FIG. 4 is a schematic sectional diagram of a structure where the hard mask layer is removed according to the present application. In step 4, after the hard mask layer 04 is removed, a side wall of the SiGe film 06 is exposed.
Step 5. A thermal treatment is performed on the stack structure in an atmosphere of ammonia and oxygen to form a SiO2-SiGe channel. Referring to FIG. 5, FIG. 5 is a schematic sectional diagram of a structure where the SiO2-SiGe channel is formed according to the present application.

According to this embodiment of the present application, a method of forming the SiO2-SiGe channel in step 5 is as follows: Ge atoms in the SiGe film 06 diffuse into the silicon layer 03 under a thermal action, and form a SiGe channel 08 with Si in the silicon layer 03; Si in the SiGe film is oxidized to form a third silicon oxide layer; and the second silicon oxide layer, the third silicon oxide layer, and the SiGe channel 09 jointly form the SiO2-SiGe channel. The second silicon oxide layer and the third silicon oxide layer jointly form the silicon oxide layer 09 in FIG. 5.

According to this embodiment of the present application, a flow of the ammonia in step 5 is 5-20 L. A temperature of the thermal treatment is 850-1100° C. A time for introducing the ammonia is 1-5 min.

According to this embodiment of the present application, a flow of the oxygen in step 5 is 30-250 ml. A time for introducing the oxygen is 30 s to 3 min. A pressure of the atmosphere of ammonia and oxygen is 3-20 torr.

To sum up, the advantage of the present application is a lower thermal budget, The SiGe channel is formed to reduce a relaxation risk of SiGe during a subsequent thermal treatment process. A small amount of oxygen is introduced at the same time when the ammonia propels Ge atoms, so as to effectively alleviate a damage on the surface of a gate oxide caused by the removal of a hard mask, effectively reduce defects of a Si/SiGe interface, and reduce a flat-band voltage Vfb of SiO2, thus obtaining the gate oxide with a better quality. Therefore, the present application effectively overcomes various defects in the prior art and thus has high industrial utilization value.

The above embodiment merely illustrates the principle and effect of the present application, rather than limiting the present application. Anyone skilled in the art can modify or change the above embodiment without departing from the spirit and scope of the present application. Therefore, all equivalent modifications or changes made by those with ordinary knowledge in the art without departing from the spirit and technical idea disclosed in the present application shall still be covered by the claims of the present application.

What is claimed is:

1. A method for forming a SiGe channel, at least comprising the following steps:
step 1, providing a fully depleted silicon on insulator (FDSOI) structure, the FDSOI structure comprising a silicon substrate, a first silicon oxide layer located on the silicon substrate, and a silicon layer located on the first silicon oxide layer, wherein the silicon layer is covered with a hard mask layer, a groove region that penetrates through upper and lower surfaces of the hard mask layer is formed on the hard mask layer, and the groove region exposes an upper surface of the silicon layer;
step 2, filling the groove region with SiGe to form a SiGe film;
step 3, forming a second silicon oxide layer on an upper surface of the SiGe film, wherein the second silicon oxide layer, the SiGe film, and the silicon layer under the SiGe film form a stack structure;
step 4, removing the hard mask layer; and
step 5, performing a thermal treatment on the stack structure in an atmosphere of ammonia and oxygen to form a SiO2-SiGe channel.

2. The method for forming the SiGe channel according to claim 1, wherein in step 2, the groove region is filled with the SiGe by means of epitaxial growth.

3. The method for forming the SiGe channel according to claim 1, wherein in step 3, the second silicon oxide layer is formed on the upper surface of the SiGe film by oxidizing the SiGe film.

4. The method for forming the SiGe channel according to claim 1, wherein a method of forming the SiO2-SiGe channel in step 5 is as follows: Ge atoms in the SiGe film diffuse into the silicon layer under a thermal action, and form a SiGe channel with Si in the silicon layer; Si in the SiGe film is oxidized to form a third silicon oxide layer; and the second silicon oxide layer, the third silicon oxide layer, and the SiGe channel jointly form the SiO2-SiGe channel.

5. The method for forming the SiGe channel according to claim 1, wherein a flow of the ammonia in step 5 is 5-20 L.

6. The method for forming the SiGe channel according to claim 1, wherein a temperature of the thermal treatment in step 5 is 850-1100° C.

7. The method for forming the SiGe channel according to claim 1, wherein a time for introducing the ammonia in step 5 is 1-5 min.

8. The method for forming the SiGe channel according to claim 1, wherein a flow of the oxygen in step 5 is 30-250 ml.

9. The method for forming the SiGe channel according to claim 1, wherein a time for introducing the oxygen in step 5 is 30 s to 3 min.

10. The method for forming the SiGe channel according to claim 1, wherein a pressure of the atmosphere of ammonia and oxygen in step 5 is 3-20 torr.
